(19) United States
(12) Patent Application Publication
(10) Pub. No.: US 2024/0400789 A1
(43) Pub. Date: Dec. 5, 2024

(54) HEAT DISSIPATION MATERIAL AND ELECTRONIC DEVICE

(71) Applicant: Hitachi Astemo, Ltd., Hitachinaka-shi, Ibaraki (JP)

(72) Inventors: Yasuhiro TSUYUKI, Chiyoda-ku, Tokyo (JP); Akihiro NAMBA, Chiyoda-ku, Tokyo (JP); Yoshio KAWAI, Hitachinaka-shi, Ibaraki (JP)

(73) Assignee: Hitachi Astemo, Ltd., Hitachinaka-shi, Ibaraki (JP)

(21) Appl. No.: 18/698,314

(22) PCT Filed: Sep. 22, 2022
(86) PCT No.: PCT/JP2022/035346

§ 371 Date: Apr. 3, 2024

(30) Foreign Application Priority Data
Oct. 20, 2021 (JP) 2021-171594

(51) Int. Cl. C08K 3/28; C08K 7/18; H05K 7/20

(52) U.S. Cl. CPC C08K 3/28; C08K 7/18; H05K 7/2039; C08K 2003/282; C08K 2201/001; C08K 2201/005

(57) ABSTRACT

A heat dissipation material that has insulating properties and uses spherical fillers includes at least one of a filler having a particle size of 200 μm or more and 1000 μm or less and having a ratio of 20% or more and a filler having a particle size of 1 nm or more and 10 μm or less and having a ratio of 20% or more, with respect to the total amount of the fillers.

### TECHNICAL FIELD

The present invention relates to a heat dissipation material and an electronic device using the heat dissipation material.

### BACKGROUND ART

As a technique related to a heat dissipation material for an electronic component mounted on an electronic device, there is a technique disclosed in PTL 1 below. PTL 1 discloses “a resin-based heat dissipation material comprising: a spherical AlN sintered powder . . . having a spherical form, an average particle size of 10 to 500 μm, and a porosity of 0.3% or less; and a synthetic resin”, and discloses that, “due to a point that the porosity of the spherical AlN sintered powder is lower than that of an AlN powder in the related art, the amount of air remaining in a pore portion during dispersion is reduced, whereby it is possible to exhibit higher thermal conductive properties”.

### CITATION LIST

### Patent Literature

PTL 1: JP 2006-206393 A

### SUMMARY OF INVENTION

### Technical Problem

In recent years, with the increase in functionality of electronic devices, a heat dissipation material for electronic components mounted on electronic devices is desired to have low dielectric properties for the purpose of achieving low noise of the electronic components in addition to heat dissipation properties. In response to such a demand, the resin-based heat dissipation material disclosed in PTL 1 is expected to improve heat dissipation properties based on high thermal conductive properties, but there is no knowledge about reduction in dielectric constant.

Therefore, an object of the present invention is to provide a heat dissipation material that is excellent in heat dissipation properties and low dielectric properties, and an electronic device capable of achieving high functionality by using the heat dissipation material as a heat dissipation material for an electronic component to be mounted.

### Solution to Problem

In order to solve the above problems, the present invention is configured as follows.

The present application includes a plurality of means for solving the above problems. As an example, in an insulating heat dissipation material using spherical fillers, a ratio of a filler having a particle size of 200 μm or more and 1000 μm or less is equal to or more than 20% and/or a ratio of a filler having a particle size of 1 nm or more and 10 μm or less is equal to or more than 20%, with respect to the total amount of the fillers.

### Advantageous Effects of Invention

According to the present invention, it is possible to provide a heat dissipation material that is excellent in heat dissipation properties and low dielectric properties, and an electronic device capable of achieving high functionality by using the heat dissipation material as a heat dissipation material for an electronic component to be mounted.

Note that problems, configurations, and effects other than those described above will be clarified by the following description of the embodiments and examples.

### BRIEF DESCRIPTION OF DRAWINGS

FIG. 1 is an external perspective view of an in-vehicle electronic control device according to an embodiment.

FIG. 2 is an exploded perspective view illustrating the in-vehicle electronic control device according to the embodiment.

FIG. 3 is an exploded perspective view of the exploded perspective view illustrated in FIG. 2 as viewed from vertically opposite sides.

FIG. 4 is a partial cross-sectional view of the in-vehicle electronic control device according to the embodiment.

FIG. 5 is a schematic view for describing a configuration of a heat dissipation material according to the embodiment.

FIG. 6 is a graph showing critical significance of a filler ratio and a porosity.

FIG. 7 is a graph showing a content and a thermal conductivity of a filler having each size in the heat dissipation material.

### DESCRIPTION OF EMBODIMENTS

Hereinafter, a heat dissipation material and an electronic device according to an embodiment of the present invention will be described in detail with reference to the drawings. In the following description, first, an embodiment in which an in-vehicle electronic control device is exemplified as an example of an electronic device will be described with reference to the accompanying drawings, and then a configuration of a heat dissipation material used in the electronic device will be described. In the drawings, the common members are denoted by the same reference signs.

### <<In-Vehicle Electronic Control Device (Electronic Device)>>

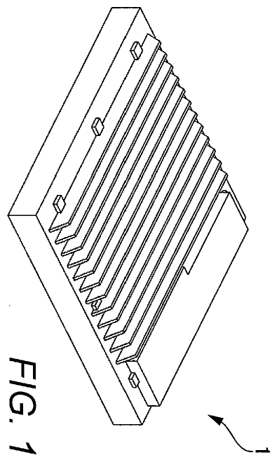

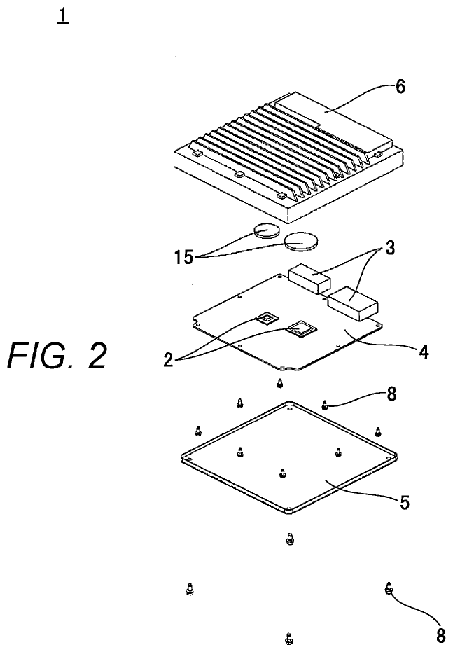

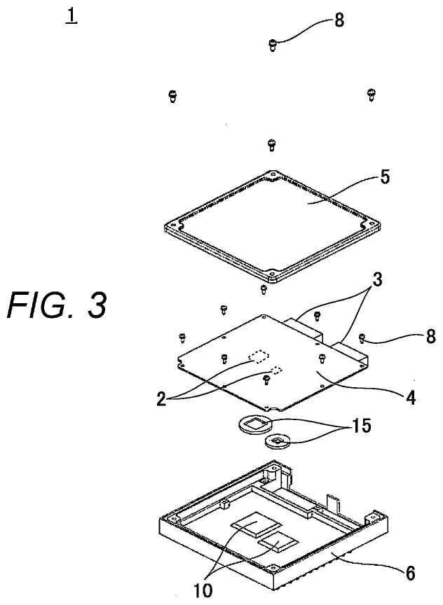

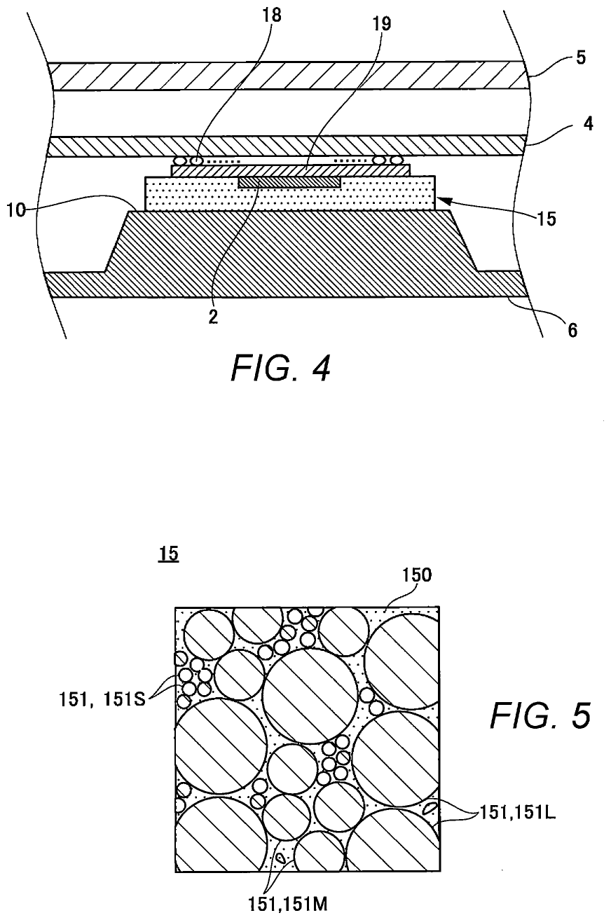

FIG. 1 is an external perspective view of an in-vehicle electronic control device 1 according to an embodiment. In addition, FIG. 2 is an exploded perspective view of the in-vehicle electronic control device 1 according to the embodiment, and FIG. 3 is a perspective view of the exploded perspective view illustrated in FIG. 2 as viewed from vertically opposite sides. Furthermore, FIG. 4 is a partial cross-sectional view of the in-vehicle electronic control device 1 according to the embodiment.

The in-vehicle electronic control device 1 illustrated in FIGS. 1, 2, 3, and 4 is installed in a room of an automobile and includes an electronic circuit that controls the automobile. As illustrated in FIGS. 2 to 4, the in-vehicle electronic control device 1 includes an electronic component 2 that generates heat, such as a semiconductor element, a connector 3, a circuit board 4, and a base 5 and a cover 6 that constitute a housing. The electronic component 2 and the circuit board 4 are mounted on the circuit board 4 and accommodated in the base 5 and the cover 6.

Among the above constituent components, the electronic component 2 here is provided for in-vehicle use, and is, for example, a semiconductor element that generates heat by a high-speed operation, such as a central processing unit (CPU), a graphics processing unit (GPU), a system on a chip (SoC), and a double data rate (DDR) memory. Such an electronic component 2 is electrically connected (mounted) to one surface or both surfaces of the circuit board 4 by using solder or the like. As a specific example, the electronic component 2 in the embodiment is electrically connected to one surface of the circuit board 4 facing the cover 6 via an interposer 19 and a solder bump 18 (illustrated only in FIG. 4). In the in-vehicle electronic control device 1 in the present embodiment, the electronic component 2 may be mounted on at least one of both surfaces of the circuit board 4.

The connector 3 (illustrated only in FIGS. 2 and 3) connects the electronic component 2 mounted on the circuit board 4 and an external device. The connector 3 has a plurality of pin terminals. The connector 3 is mounted on the circuit board 4 by connecting the pin terminals to the circuit board 4 by press fitting, soldering, or the like. The connector 3 is electrically connected to the circuit board 4 via the pin terminals.

As the circuit board 4, for example, a general laminated wiring board including thermosetting resin, a glass cloth, and a metal wiring on which a circuit pattern is formed, a wiring board including ceramics and a metal wiring, a wiring board including a flexible substrate of polyimide or the like and a metal wiring, or the like is used. Screw holes are formed at four corners of the circuit board 4. Then, the circuit board 4 is fixed to the base 5 and the cover 6 by fixing screws 8. In addition, a detailed configuration of a portion of the circuit board 4 at which the electronic component 2 is mounted will be described later.

The base 5 is formed in a substantially flat plate shape. Screw holes are formed at four corners of the end portion of the base 5. The base 5 is disposed in a state where the circuit board 4 is sandwiched between the base 5 and the cover 6, and is integrally fixed to the circuit board 4 and the cover 6 by the fixing screws 8.

The cover 6 has a hollow box shape with one surface opened, and a box-shaped bottom surface thereof is formed in a substantially rectangular shape. A heat dissipation seat 10, which is a plurality of protrusions, is formed on a bottom surface of the cover 6 facing the opening surface. The heat dissipation seat 10, which is the protrusion, protrudes from the cover 6 toward the circuit board 4. The heat dissipation seat 10 is provided at a position facing the electronic component 2 mounted on the circuit board 4 when the circuit board 4 is placed in a hollow space of the cover 6. In addition, the plurality of electronic components 2 may face one heat dissipation seat 10. Further, screw holes are formed at four corners of an end portion of the cover 6 at which the opening is formed. The cover 6 accommodates the circuit board 4 in the hollow space and is installed to sandwich the circuit board 4 with the base 5. Then, the circuit board 4, the base 5, and the cover 6 are integrally fixed by fastening the fixing screw 8 to the screw holes of the base 5, the cover 6, and the circuit board 4.

Note that the base 5 and the cover 6 are formed by, for example, casting, pressing, cutting, injection molding, or the like. As the material forming the base 5 and the cover 6, an alloy containing aluminum as a main component is preferable, for example, if the base 5 and the cover 6 are made of metal. The base 5 and the cover 6 may be formed of high thermal conductive resin in which resin and a filler are mixed. The thermal conductivity of the high thermal conductive resin is preferably 2 to 30 W/(m·K). Further, the base 5 and the cover 6 are not limited to the composite material, and the base 5 and the cover 6 may be formed of only a resin or a metal material.

In addition, as the resin for forming the base 5 and the cover 6, polybutylene terephthalate resin (PBT), polyphenylene sulfide resin (PPS), polyamide resin (PA6), or the like is preferably used. Further, as the filler, any of glass fiber, carbon fiber, alumina (Al₂O₃), and the like is preferably used. Then, the metal forming the base 5 and the cover 6 may be magnesium or steel in addition to aluminum (Al) or an alloy containing aluminum as a main component.

Next, a detailed configuration of a portion at which the electronic component 2 is mounted in the in-vehicle electronic control device 1 will be described with reference to FIG. 4.

FIG. 4 is a partial cross-sectional view of the in-vehicle electronic control device 1 according to the embodiment, and is a cross-sectional view illustrating the circuit board 4 and the heat dissipation seat 10.

As illustrated in FIG. 4, a heat dissipation material 15 is sandwiched between the electronic component 2 and the cover 6, which is the housing, at the portion of the circuit board 4 at which the electronic component 2 is mounted. More specifically, a space between the interposer 19 for mounting the electronic component 2 on the circuit board 4 and the heat dissipation seat 10 provided at the cover 6 is filled with the heat dissipation material 15 in a state of covering the electronic component 2. In this state, the heat dissipation material 15 is preferably in direct contact with the heat dissipation seat 10 and the electronic component 2. As a result, the heat dissipation material 15 thermally connects the heat dissipation seat 10 to the electronic component 2, further, the circuit board 4 via the interposer 19 and the solder bump 18, and adheres the heat dissipation seat 10 and the circuit board 4 to each other. Then, heat generated in the electronic component 2 is dissipated by the heat dissipation material 15 to the outside via the interposer 19, the solder bump 18, and the circuit board 4. Alternatively, the heat generated in the electronic component 2 is dissipated by the heat dissipation material 15 from the heat dissipation seat 10 to the outside via the cover 6.

Note that, when the electronic component 2 is mounted on the side of the circuit board 4 facing the base 5, the heat dissipation seat 10 is formed at the base 5. That is, the heat dissipation seat 10 coated with the heat dissipation material 15 is formed on the surface of the housing having the base 5 and the cover 6, which faces the electronic component 2.

The heat dissipation material 15 has a function as a resin material adhesive or grease (lubricant), and has a configuration in which sheet-like thermosetting resin is used as a base material and a filler having high thermal conductivity is dispersed in the resin being the base material. A configuration of the heat dissipation material 15 will be described below.

### <<Heat Dissipation Material 15>>

FIG. 5 is a schematic view for describing the configuration of the heat dissipation material 15 according to the embodiment. As illustrated in FIG. 5, the heat dissipation material 15 is obtained by mixing and dispersing a filler 151 with respect to resin 150, and is a mixture of the resin 150 and the filler 151.

The resin 150 is preferably thermosetting resin, and as a result, in an assembly of the electronic device 1 illustrated in FIG. 4, the resin 150 can be made effective by heating without light irradiation, in a state where the electronic component 2 and the heat dissipation material are sandwiched between the circuit board 4 and the cover 6. As an example of such resin 150, silicone resin is exemplified. The silicone resin is a synthetic polymer having a main skeleton formed of a siloxane bond (Si—O—Si). The silicone resin exhibits a rubber property and has small stress on a heat dissipation device, and thus is often used as the resin 150 for the base material of the heat dissipation material 15.

The filler 151 is made of, for example, aluminum nitride. Aluminum nitride is a solid compound composed of nitrogen and aluminum, and has a spherical shape close to a true sphere. The filler 151 made of aluminum nitride is excellent in thermal conductive properties, heat resistance, corrosion resistance, electrical insulating properties, and lubricity/releasability, and can be mixed with various types of resins. Since the spherical filler 151 has isotropic thermal conductive properties, the thermal conduction path in the heat dissipation material 15, which is formed by the spherical filler 151, isotropically spreads. Thus, the heat dissipation material 15 in which the spherical filler 151 is dispersed in the resin 150 is excellent in heat dissipation properties as compared with a heat dissipation material in which a filler having anisotropic thermal conductive properties due to a fiber shape such as carbon fiber is dispersed in the resin.

In addition, the filler 151 made of aluminum nitride has a thermal conductivity close to 200 W/mK, and high thermal conduction can be expected. Further, the aluminum nitride has a certain degree of rigidity. Therefore, even at the time of kneading the resin 150 and the filler 151, in particular, the filler having a large particle size easily maintains the original particle size, and it is possible to realize a filling structure of an ideal filler 151 in the heat dissipation material 15 as described below.

Note that it is assumed that the filler 151 is not limited to one made of aluminum nitride as long as the thermal conductivity is 1 to 200 W/mK, and may be one formed of aluminum oxide, zinc oxide, magnesium oxide, or silicon dioxide. The fillers 151 made of the above materials also have a spherical shape.

### <Content of Filler 151>

The content of the filler 151 in the heat dissipation material 15 is defined as a volume fraction of the filler 151 when the volume of the heat dissipation material 15 is set to 100 vol %. Such a content of the filler 151 is preferably 40 vol % or more, and more preferably 30 vol % or more, from the viewpoint of securing high thermal conductive properties and a low dielectric constant of the heat dissipation material 15. Furthermore, the content of the filler 151 is preferably set to be 20 vol % or more. Note that the upper limit value of the content of the filler 151 is set in a range in which the heat dissipation material 15 can be obtained by being mixed and integrated with the resin 150 being the base material, and is about 95 vol %. In such a heat dissipation material 15, it is assumed that the resin 150 that can integrate the filler 151 as the heat dissipation material 15 is filled between the filler 151 and the filler 151.

In a content range of the filler 151 as described above, even when the content of the filler 151 is set to be low for the purpose of lowering the dielectric constant of the heat dissipation material 15, it is possible to realize high thermal conduction by optimizing the diameter of the filler 151. In addition, as the content of the filler 151 becomes lower, the dielectric constant of the entire heat dissipation material 15 becomes lower, and thus it makes possible to reduce noise of an electronic component mounted on an electronic device by using the heat dissipation material 15.

A method of calculating the content of the filler 151 in the heat dissipation material 15 is not particularly limited. For example, the heat dissipation material 15 which is a mixture of the filler 151 and the resin 150 is decomposed and then examined. As an example, in the case of a mixture (heat dissipation material 15) using silicone resin, the resin 150 is dissolved by exposing a predetermined volume of the mixture to n-hexane, and the component of the filler 151 is separated by filtering an n-hexane solution in which the resin 150 is dissolved. The volume of the separated filler 151 can be calculated based on the mass of the filler 151 and the density of the material (for example, aluminum nitride) forming the filler 151, and the content of the filler 151 in the mixture can be calculated from the calculated volume of the filler 151 and the volume of the mixture.

### <Particle Size of Filler 151>

The diameter (hereinafter, also referred to as a particle size) of particles of the filler 151 to be mixed with the resin 150 is the length of the particles of the filler 151, which is measured in accordance with a rule determined by the shape of the particles of the filler 151. When the shape of the particles of the filler 151 is spherical, the diameter of the particles of the filler 151 is defined as the diameter of the particles of the filler 151. When the shape of the particles of the filler 151 is amorphous, the diameter of the major axis of the particles of the filler 151 is defined as the particle size of the filler 151.

It is assumed that the major axis of the particles of the filler 151 is determined by, for example, observing the particle with a device that can directly observe the shape, such as a scanning electron microscope, and reflecting the result of quantitatively measuring the shape and the length thereof. In addition, the length of the major axis of the particles of the filler 151 at this time is measured by using a length measuring function of a scanning electron microscope in addition to a particle size distribution measuring device.

### <Particle Size Distribution of Filler 151>

From a result of examination shown in the following examples, it has been confirmed that high thermal conduction of the heat dissipation material 15 can be achieved if the particle size distribution of the filler 151 in the heat dissipation material 15 is as follows. Here, a filler 151 having a particle size of 200 μm or more (described as 200 μm or more) is referred to as a large-diameter filler 151L. The upper limit value of the particle size of the large-diameter filler 151L is an upper limit value in manufacturing the filler 151, and is currently about 200 μm. In addition, a filler 151 having a particle size of 1 nm or more and 10 μm or less (described as 1 nm to 10 μm) is referred to as a small-diameter filler 151S. A filler 151 having an intermediate particle size of more than 10 μm and less than 200 μm (described as 10 μm to 200 μm) is referred to as a medium-diameter filler 151M.

In the heat dissipation material 15, with respect to the total amount of the filler 151, the ratio of the large-diameter filler 151L is 20% or more, or the ratio of the small-diameter filler 151S is 20% or more, or both cases are provided. Note that this ratio is a volume ratio, and the same applies below. In addition, when the filler 151 is mixed with the resin 150, the components of the filler 151 preferably include large-diameter fillers 151L having a particle size of 200 μm or more and small-diameter fillers 151S having a particle size of 1 nm to 10 μm in the filler 151.

In the filler 151 dispersed in the resin 150, it is more preferable that the ratio of the large-diameter filler 151L is 20% or more, or the ratio of the small-diameter filler 151S is 20% or more. Here, when the ratio of the large-diameter filler 151L is 20% or more, the filler 151 of less than 80% other than the large-diameter filler 151L is at least one of the small-diameter filler 151S and the medium-diameter filler 151M. Note that the upper limit value of the ratio of the large-diameter filler 151L with respect to the total amount of the filler 151 is an upper limit value in manufacturing the filler 151, similarly to the upper limit value of the particle size of the filler 151, and is currently about 30%. In addition, when the ratio of the small-diameter filler 151S is 20% or more, the filler 151 of less than 80% other than the small-diameter filler 151S is at least one of the large-diameter filler 151L and the medium-diameter filler 151M, but the filler 151 contained in the heat dissipation material 15 may be only the small-diameter filler 151S.

Further, in the particle size distribution of the filler 151 dispersed in the resin 150, it is further preferable that the ratio of the large-diameter filler 151L is 20% or more and the ratio of the small-diameter filler 151S is 20% or more. In this case, the filler 151 of less than 60% with respect to the total amount of the filler 151 other than the large-diameter filler 151L and the small-diameter filler 151S is the medium-diameter filler 151M, but the filler 151 contained in the heat dissipation material 15 may be only the large-diameter filler 151L and the small-diameter filler 151S.

A method of measuring the particle size distribution of the filler 151 dispersed in the resin 150 is not particularly limited, and for example, the particle size distribution is examined by a laser diffraction/scattering particle size distribution measuring device. The laser diffraction method is a method of irradiating a sample with laser light and obtaining a particle size distribution of the sample from an intensity pattern of diffracted/scattered light.

The porosity between the fillers 151 in the heat dissipation material 15 is defined as a volume of a gap between the fillers 151 in a unit volume in a unit volume of a space including the filler 151. The gap between the fillers 151 in the heat dissipation material 15 is a portion filled with the resin 150 or a space portion.

For example, a mixture (heat dissipation material 15) in which the filler 151 is dispersed in the resin 150 is exposed to a solvent such as hexane to dissolve the resin 150, and then the total ratio of gaps existing in the fillers 151 as a lump is the porosity.

As the porosity is lower, the filling state of the filler 151 in the heat dissipation material 15, which is a mixture of the resin 150 and the filler 151, approaches closest filling, the gap between the fillers 151 becomes smaller, and a heat conduction path is formed, so that it is possible to achieve high thermal conduction. As a result of the following examination, it is understood that the porosity is preferably 22% or less, and more preferably 7% or less.

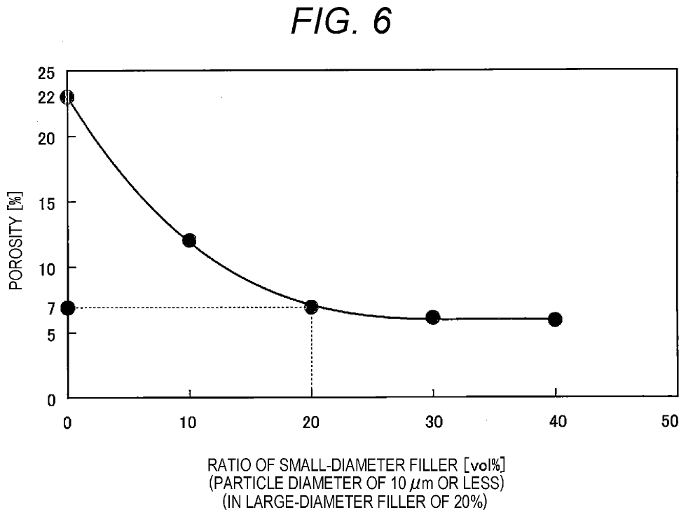

FIG. 6 is a graph showing critical significance of the filler ratio and the porosity. FIG. 6 is a graph in which, when the ratio of the large-diameter filler 151L is fixed to 20% with respect to the total amount of the fillers 151 contained in the heat dissipation material 15, the ratio of the small-diameter filler 151S is taken as the horizontal axis, and the porosity between the fillers 151 in the heat dissipation material 15 is taken as the vertical axis. Note that the fillers other than the large-diameter filler 151L of 20% and the small-diameter filler 151S of each ratio are the medium-diameter filler 151M. The porosity is a result calculated by inputting data of the particle size distribution of the filler 151 into porosity simulation software. As shown in this graph, the porosity was 22% when the large-diameter filler 151L was 20% and the small-diameter filler 151S was 0%, and it was confirmed that the porosity decreased when the ratio of the small-diameter filler 151S increased. As a result, it is understood that even the small-diameter filler 151S having a particle size of 1 nm to 10 μm contributes to improvement in thermal conductivity due to reduction in porosity by being contained in the heat dissipation material 15. Then, when the ratio of the large-diameter filler 151L is 20%, during a period in which the ratio of the small-diameter filler 151S increases to 20%, the porosity largely decreases from 22% to 7%, and when the ratio of the small-diameter filler 151S is set to be 20% or more, it is possible to decrease the porosity to 7% or less.

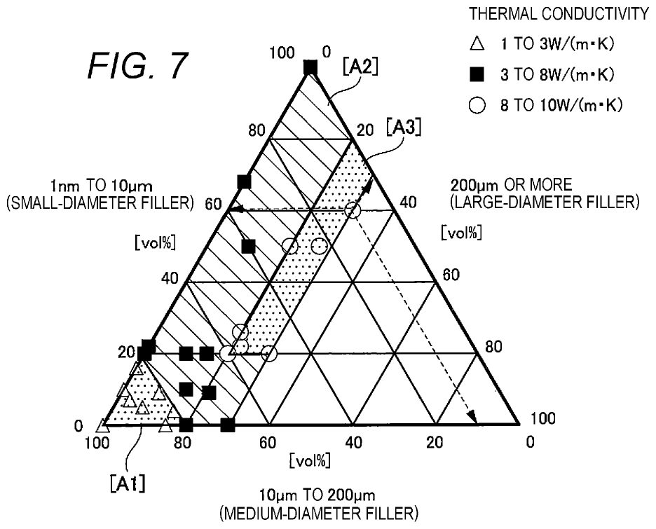

FIG. 7 is a graph showing the ratio of each diameter filler in the heat dissipation material and the thermal conductivity, and illustrates an example of the particle size distribution of the filler 151 made of aluminum nitride and the measurement result of the thermal conductivity.

In FIG. 7, in a range [A1] of the particle size distribution in which the ratio of the small-diameter filler 151S is less than 20% and the ratio of the large-diameter filler 151L is less than 20%, the thermal conductivity was 1 to 3 W/(m·K).

In addition, in a range [A2] of the particle size distribution in which the ratio of the small-diameter filler 151S was 20% or more, or the ratio of the large-diameter filler 151L was 20% or more, the thermal conductivity was 3 to 8 W/(m·K).

In a range [A3] in which the ratio of the small-diameter filler 151S was 20% or more and the ratio of the large-diameter filler was 20% or more, the thermal conductivity was 8 to 10 W/(m·K).

From the experimental results illustrated in FIG. 7, it is understood that, in the particle size distribution of the filler 151 made of aluminum nitride, from the viewpoint of thermal conductivity, the ratio of the small-diameter filler 151S is preferably 20% or more, or the ratio of the large-diameter filler 151L is preferably 20% or more, and it is more preferable that both cases are satisfied.

### EXAMPLES

Next, each example of a heat dissipation material used in the in-vehicle electronic control device having the configuration described in the embodiment will be described together with a comparative example with reference to FIG. 5. Note that, in each of Examples and Comparative Examples, a mixture serving as a heat dissipation material was prepared by using the filler 151 made of aluminum nitride and the resin 150 made of silicone.

### Example 1

Example 1 of the present invention will be described. Table 1 below shows the configuration of the mixture serving as the heat dissipation material 15 prepared in Example 1.

In Example 1, the content of the filler 151 was adjusted to 70 vol %, and the filler 151 and the resin 150 were mixed. The particle size distribution of the filler 151 was adjusted so that the ratio of the small-diameter filler 151S having a particle size of 1 nm to 10 μm was 60%, the ratio of the medium-diameter filler 151M having a particle size of 10 to 200 μm was 10%, and the ratio of the large-diameter filler 151L having a particle size of 200 μm to 1000 μm was 30%.

The materials mixed as described above were heated and cured at 120° C. for 90 minutes. As a result, a mixture of the content of the filler 151 and the range of the particle size distribution described in the embodiment was prepared as a mixture of Example 1.

### Comparative Example 1

Next, Comparative Example 1 of the present invention will be described. Table 1 below shows the configuration of a mixture prepared in Comparative Example 1.

In Comparative Example 1, the content of the filler 151 was adjusted to 80 vol %, and the filler 151 and the resin 150 were mixed. The particle size distribution of the filler 151 was adjusted so that the ratio of the medium-diameter filler 151M was 100%.

The materials mixed as described above were heated and cured under the similar conditions to those of Example 1 to prepare a mixture of Comparative Example 1.

### Comparative Example 2

Next, Comparative Example 2 of the present invention will be described. Table 1 below shows the configuration of a mixture prepared in Comparative Example 2.

In Comparative Example 2, the content of the filler 151 was adjusted to 94 vol %, and the filler 151 and the resin 150 were mixed. The particle size distribution of the filler 151 was adjusted so that the particle size of 10 μm to 500 μm described in PTL 1 was 100%.

The materials mixed as described above were heated and cured under the similar conditions to those of Example 1 to prepare a mixture of Comparative Example 2.

TABLE 1

| | Example | Comparative | Comparative |
|---|---|---|---|
| | 1 | Example 1 | Example 2 |
| Filler content | 70 | 80 | 94 |
| (vol %) | | | |
| Ratio | 60 | 0 | 0 |
| (small-diameter | | | |
| filler) of | | | |
| 1 nm to 10 μm | | | |
| (%) | | | |
| Ratio | 10 | 100 | 100 |
| (medium-diameter | | | (10 to 500 μm) |
| filler) of | | | |
| 10 μm to 200 μm | | | |
| (%) | | | |
| Ratio | 30 | 0 | 0 |
| (large-diameter | | | |
| filler) of | | | |
| 200 μm or more | | | |
| (%) | | | |
| Thermal | 9.6 | 5.0 | 9.5 |
| conductivity | | | |
| (W/mk) | | | |
| Dielectric constant | 8 | 8 | 9 to 9.5 |
| (—) | | | |
| Noise level | 21 | 20 | 35 |
| @1.6 GHz | | | |
| (dBμV/m) | | | |

### (Evaluation Results of Example 1 and Comparative Examples 1 and 2)

Each mixture prepared in Example 1 and Comparative Examples 1 and 2 was processed to a thickness of 1 mm, and the thermal diffusivity was measured by using a thermal diffusivity measuring device. The thermal conductivity of each mixture was obtained by multiplying the measured thermal diffusivity by the density measured by the Archimedes method and the specific heat measured by a DSC (differential scanning calorimetry) method as a thermal analysis method. In addition, the dielectric constant and the noise level of each mixture were measured. These results are shown in Table 1 above. Note that the noise level in the 1.6 GHz band is shown as a representative value.

As shown in Table 1, the mixture prepared in Example 1 has a content of the filler 151 lower than the content of the mixture of Comparative Examples 1 and 2. However, it is understood that the thermal conductivity of the mixture prepared in Example 1 is higher than the thermal conductivity of the mixture of Comparative Example 1, and is as high as the thermal conductivity of the mixture of Comparative Example 2. Furthermore, the dielectric constant of the mixture prepared in Example 1 is about the same as the thermal conductivity of the mixture of Comparative Example 1, and is lower than the dielectric constant of the mixture of Comparative Example 2.

From the above results, it was confirmed that, even when the content of the filler 151 is set to be low for the purpose of reducing the dielectric constant, it is possible to improve the thermal conductivity by optimizing the particle size distribution of the filler 151, and it is possible to obtain a heat dissipation material having a high thermal conductivity but a low dielectric constant. As a result, it was confirmed that, by mounting the electronic component using the heat dissipation material with the adjusted particle size distribution, it is possible to secure the heat dissipation properties of the electronic component and to suppress the noise level to be low, and it is possible to obtain an in-vehicle electronic control device that achieves high functionality.

### Examples 2 to 7 and Comparative Example 3

Examples 2 to 7 and Comparative Example 3 of the present invention will be described. Table 2 below shows the configuration of the mixture serving as the heat dissipation material prepared in Examples 2 to 7 and Comparative Example 3. In Examples 2 to 7 and Comparative Example 3, the content of the filler 151 was adjusted so that the dielectric constant of each mixture was about 7 to 7.5, and the filler 151 and the resin 150 were mixed. The particle size distribution of the filler 151 in Examples 2 to 7 and Comparative Example 3 is as shown in Table 2. In addition, in Examples 2 to 7 and Comparative Example 3, the mixed materials were heated and cured under the similar conditions to those of Example 1 to prepare each mixture.

TABLE 2

| | Example | Example | Example | Example | Example | Example | Comparative |
|---|---|---|---|---|---|---|---|
| | 2 | 3 | 4 | 5 | 6 | 7 | Example 3 |
| Ratio | 20 | 0 | 0 | 22 | 68 | 100 | 0 |
| (small-diameter | | | | | | | |
| filler) of 1 nm | | | | | | | |
| to 10 μm (%) | | | | | | | |
| Ratio | 80 | 80 | 70 | 78 | 32 | 0 | 100 |
| (medium-diameter | | | | | | | |
| filler) of 10 μm | | | | | | | |
| to 200 μm (%) | | | | | | | |
| Ratio | 0 | 20 | 30 | 0 | 0 | 0 | 0 |
| (large-diameter | | | | | | | |
| filler) of 200 μm | | | | | | | |
| or more (%) | | | | | | | |
| Thermal | 3.5 | 4.1 | 4.0 | 3.6 | 4.1 | 3.2 | 2.5 |
| conductivity | | | | | | | |
| (W/mK) | | | | | | | |

### (Evaluation Results of Examples 2 to 7 and Comparative Example 3)

The thermal conductivity of each of the mixtures prepared in Examples 2 to 7 and Comparative Example 3 was obtained in the similar procedure to that in Example 1 and Comparative Examples 1 and 2. The results are shown in Table 2 above.

From Table 2, it is understood that the thermal conductivity of the mixture of Examples 2 and 5 to 7 in which the ratio of the small-diameter filler 151S is 20% or more is higher than the thermal conductivity of the mixture of Comparative Example 3 in which the medium-diameter filler 151M is 100%. In addition, it is found that the thermal conductivity of the mixture of Examples 3 and 4 in which the ratio of the large-diameter filler 151L is 20% or more is higher than the thermal conductivity of the mixture of Comparative Example 3 in which the medium-diameter filler 151M is 100%.

From the above results, it has been confirmed that the mixture of Examples 2 to 7 in the scope of the present invention in which the ratio of the small-diameter filler 151S is 20% or more, or the ratio of the large-diameter filler 151L is 20% or more is a heat dissipation material having a high thermal conductivity while having a low dielectric constant to the same extent as the mixture of Comparative Example 3.

### Examples 8 to 12

Next, Examples 8 to 12 of the present invention will be described. Table 3 below shows the configuration of the mixture serving as the heat dissipation material prepared in Examples 8 to 12. In Examples 8 to 12, the content of the filler 151 was adjusted so that the dielectric constant of each mixture was about 7 to 7.5, and the filler 151 and the resin 150 were mixed. The particle size distribution of the filler 151 in Examples 8 to 12 is as shown in Table 3. In addition, in Examples 8 to 12, the mixed materials were heated and cured under the similar conditions to those of Example 1 to prepare each mixture.

TABLE 3

| | Exam- | Exam- | Exam- | Exam- | Exam- |
|---|---|---|---|---|---|
| | ple | ple | ple | ple | ple |
| | 8 | 9 | 10 | 11 | 12 |
| Ratio | 20 | 20 | 9 | 11 | 50 |
| (small-diameter | | | | | |
| filler) of | | | | | |
| 1 nm to 10 μm | | | | | |
| (%) | | | | | |
| Ratio | 70 | 65 | 71 | 68 | 40 |
| (medium-diameter | | | | | |
| filler) of | | | | | |
| 10 μm to 200 μm | | | | | |
| (%) | | | | | |
| Ratio | 10 | 15 | 20 | 21 | 10 |
| (large-diameter | | | | | |
| filler) of 200 μm | | | | | |
| or more (%) | | | | | |
| Thermal | 5.5 | 6.8 | 6.9 | 7.5 | 7.8 |
| conductivity | | | | | |
| (W/mk) | | | | | |

### (Evaluation Results of Example 8 to 12)

The thermal conductivity of each of the mixtures prepared in Examples 8 to 12 was obtained in the similar procedure to that in Example 1 and Comparative Examples 1 and 2. The results are shown in Table 3 above.

From Table 3, it is understood that the thermal conductivity of the mixture of Examples 8, 9, and 12 in which the ratio of the small-diameter filler 151S is 20% or more and the medium-diameter filler 151M and the large-diameter filler 151L having a particle size of more than 10 μm are contained is higher than the thermal conductivity of the mixture of Examples 2 to 7 shown in Table 2. In addition, it is understood that the thermal conductivity of the mixture of Examples 10 and 11 in which the ratio of the large-diameter filler 151L is 20% or more and the medium-diameter filler 151M and the small-diameter filler 151S having a particle size of less than 200 μm are contained is higher than the thermal conductivity of the mixture of Examples 2 to 7 shown in Table 2.

From the above results, it has been confirmed that, when the particle size distribution of the filler 151 in the heat dissipation material 15 has a configuration in which the ratio of the small-diameter filler 151S is 20% or more and the filler having a particle size of more than 10 μm is contained, or a configuration in which the ratio of the large-diameter filler 151L is 20% or more and the filler having a particle size of less than 200 μm is contained, both the low dielectric constant and the high thermal conductivity is achieved.

### Examples 13 to 18

Next, Examples 13 to 18 of the present invention will be described. Table 4 below shows the configuration of the mixture serving as the heat dissipation material prepared in Examples 13 to 18. In Examples 13 to 18, the content of the filler 151 was adjusted so that the dielectric constant of each mixture was about 8, and the filler 151 and the resin 150 were mixed. The particle size distribution of the filler 151 in Examples 13 to 18 is as shown in Table 4. In addition, in Examples 13 to 18, the mixed materials were heated and cured under the similar conditions to those of Example 1 to prepare each mixture.

TABLE 4

| | Example | Example | Example | Example | Example | Example |
|---|---|---|---|---|---|---|
| | 13 | 14 | 15 | 16 | 17 | 18 |
| Ratio | 22 | 26 | 20 | 20 | 50 | 50 |
| (small-diameter | | | | | | |
| filler) of 1 nm | | | | | | |
| to 10 μm (%) | | | | | | |
| Ratio | 56 | 54 | 60 | 50 | 30 | 23 |
| (medium-diameter | | | | | | |
| filler) of 10 μm | | | | | | |
| to 200 μm (%) | | | | | | |
| Ratio | 20 | 20 | 20 | 30 | 20 | 27 |
| (large-diameter | | | | | | |
| filler) of 200 μm | | | | | | |
| or more (%) | | | | | | |
| Thermal | 8.1 | 8.4 | 8.1 | 8.3 | 8.7 | 9.1 |
| conductivity | | | | | | |
| (W/mK) | | | | | | |

### (Evaluation Results of Example 13 to 18)

The thermal conductivity of each of the mixtures prepared in Examples 13 to 18 was obtained in the similar procedure to that in Example 1 and Comparative Examples 1 and 2. The results are shown in Table 4 above.

From Table 4, it is understood that the thermal conductivity of the mixture of Examples 13 to 18 in which the ratio of the small-diameter filler 151S is 20% or more and the ratio of the large-diameter filler 151L is 20% or more is higher than the thermal conductivity of the mixture of Examples 8 to 12 shown in Table 3. In addition, in comparison of the mixture of Examples 13 to 15 and 17 in which the ratio of the large-diameter filler 151L is 20%, the thermal conductivity is higher when the ratio of the small-diameter filler 151S is higher. As a result, it is predicted that the gap between the large-diameter fillers 151L is filled with the small-diameter fillers 151S, the filling state of the fillers in the mixture is improved, and the thermal conductivity is increased.

From the above results, it has been confirmed that, when the particle size distribution of the filler 151 in the heat dissipation material 15 is configured such that the ratio of the small-diameter filler 151S is 20% or more and the ratio of the large-diameter filler 151L is 20% or more, both the lower dielectric constant and the higher thermal conductivity are achieved.

The present invention is not limited to the embodiment and the examples described above, and various modification examples may be further provided. For example, the above embodiment has been described in detail in order to explain the present invention in an easy-to-understand manner, and the above embodiment is not necessarily limited to a case including all the described configurations. Further, some components in one embodiment can be replaced with the components in another embodiment, and the configuration of another embodiment can be added to the configuration of one embodiment. Regarding some components in the embodiment, other components can be added, deleted, and replaced.

For example, the heat dissipation material according to the present invention can be applied as a heat dissipation material used for not only an in-vehicle electronic control device but also an inverter, a converter, or the like other than an in-vehicle device.

### REFERENCE SIGNS LIST

1 in-vehicle control device
2 electronic component
5 base (housing)
6 cover (housing)
10 heat dissipation seat
15 heat dissipation material
150 resin
151 filler

1. A heat dissipation material that has insulating properties and uses spherical fillers, the heat dissipation material comprising
at least one of a filler having a particle size of 200 μm or more and 1000 μm or less and having a ratio of 20% or more and a filler having a particle size of 1 nm or more and 10 μm or less and having a ratio of 20% or more, with respect to a total amount of the fillers.

2. The heat dissipation material according to claim 1, wherein the filler is made of a material having a thermal conductivity of 1 W/mK to 200 W/mK.

3. The heat dissipation material according to claim 1, wherein the fillers are aluminum nitride.

4. The heat dissipation material according to claim 3, wherein a content of the fillers is 20 vol % or more and 95 vol % or less.

5. The heat dissipation material according to claim 1, wherein a ratio of a filler having a particle size of 200 μm or more and 1000 μm or less is equal to or more than 20% with respect to the total amount of the fillers, and a filler having a particle size of less than 200 μm is contained.

6. The heat dissipation material according to claim 1, wherein a ratio of a filler having a particle size of 1 nm or more and 10 μm or less is equal to or more than 20% with respect to the total amount of the fillers, and a filler having a particle size of more than 10 μm is contained.

7. The heat dissipation material according to claim 1, wherein, with respect to the total amount of the fillers, a ratio of a filler having a particle size of 200 μm or more and 1000 μm or less is equal to or more than 20%, and a ratio of a filler having a particle size of 1 nm or more and 10 μm or less is equal to or more than 20%.

8. The heat dissipation material according to claim 1, wherein the fillers are dispersed in resin.

9. The heat dissipation material according to claim 8, wherein the resin is thermosetting resin.

10. The heat dissipation material according to claim 8, wherein the resin is silicone resin.

11. An electronic device comprising:
a circuit board on which an electronic component is mounted; and
a housing that accommodates the circuit board inside,
wherein the heat dissipation material according to claim 1 is sandwiched between the electronic component and the housing.

12. The electronic device according to claim 11, wherein
a heat dissipation seat that protrudes toward the electronic component is provided at a position facing the electronic component in the housing, and
the heat dissipation material is sandwiched between the electronic component and the heat dissipation seat.

13. The electronic device according to claim 11, wherein the electronic component is at least one of a CPU, a GPU, an SoC, and a DDR memory.

14. The electronic device according to claim 11, wherein the electronic component is an in-vehicle electronic component.
